(19) United States
(12) Patent Application Publication
(10) Pub. No.: US 2020/0048079 A1
(43) Pub. Date: Feb. 13, 2020

(54) A PRINTING METHOD OF MANUFACTURING NANOBEAM STRUCTURES

(71) Applicant: DALIAN UNIVERSITY OF TECHNOLOGY, Dalian, Liaoning (CN)

(72) Inventors: Dazhi WANG, Dalian, Liaoning (CN); Xiaojun ZHAO, Dalian, Liaoning (CN); Tongqun REN, Dalian, Liaoning (CN); Junsheng LIANG, Dalian, Liaoning (CN)

(21) Appl. No.: 16/340,655

(22) PCT Filed: Feb. 5, 2018
(86) PCT No.: PCT/CN2018/075330

§ 371 Date: Apr. 9, 2019

(30) Foreign Application Priority Data
Aug. 10, 2017 (CN) 201710678423.2

(51) Int. Cl. B81C 1/00

(52) U.S. Cl. CPC B81C 1/00373; B81C 2201/0185

(57) ABSTRACT

A method of manufacturing a nanobeam structure by printing, namely coaxial focused electrohydrodynamic jet printing. In this method, under the combined action of electric field, thermal field and flow field, a stable coaxial jet is formed and used to print linear bilayer encapsulated structure on a substrate with a prefabricated support structure. Within the coaxial jet, the nanoscale inner liquid consisting of functional material is encapsulated by the microscale outer liquid consisting of high viscous material, which has the capability to directly print functional nanobeam structures. This high viscous material eliminates the disturbance of external micro-environment, and plays a role of supporting the printed inner structure before complete solidification of the inner material. A nanobeam structure only consisting of inner function material is formed on the substrate when the outer high viscous encapsulated material is removed.

### TECHNICAL FIELD

The present invention belongs to the technical field of advanced manufacturing, and relates to a printing method of manufacturing nanobeam structures.

### BACKGROUND

The nanodevices have a wide application prospect in the fields of energy, environment, biology and medical care due to their outstanding properties such as high sensitivity, low power consumption and high integration, for example, high-sensitivity nanowire sensor, high-capacity nano-memory and high on-off-ratio nano-transistor. In the structure of high-performance nanodevice, beam structures of the nano-freebeam and the nano-cantilever beam play important role owning to their advantages of large specific surface area, high sensitivity and easy excitation. At present, the manufacturing methods of nanobeam structures mainly include the crystal growth method and the transfer method. The crystal growth method is a method of longitudinally growing nanowires on two adjacent substrates respectively by laser ablation, hydrolyzation, electrochemical deposition and so on. Then, a nanobeam structures will be formed when the nanowires on the two adjacent substrates grow to a certain height, and then the upper ends of the nanowires come into contact with each other. However, the shape and size of nanobeam prepared using this method is difficult to control, and the reliability of the nanodevice manufactured by this nanobeam structure is poor due to the low contact strength of the nanobeam at the overlapping part. Furthermore, this method is low in manufacturing efficiency. The transfer method is a method of transferring the nanowires onto a substrate to obtain nanobeam structures by using the precise micromanipulation technique. The applied nanowires are prepared by the crystal growth method, electron beam and so on, and the supporting structure is prefabricated on the substrate. This method of preparing nanobeam structure have the disadvantages of complicated process, expensive equipment and low efficiency.

### SUMMARY

In order to overcome the defects of the above mentioned techniques of manufacturing nanobeam, a printing method of manufacturing nanobeam structure is invented, named coaxial focused electrohydrodynamic jet printing. In this method, under the combined action of electric field, thermal field and flow field, a stable coaxial jet is formed and used to print linear bilayer encapsulated structure on a substrate. In the coaxial jet, the nanoscale inner liquid of functional material is encapsulated by the microscale outer liquid of high viscous material. After printing, due to the effect of thermal field, the inner function material and the outer high viscous material are respectively solidified and semi-solidified, and the semi-solidified outer high viscous material plays a role of supporting the inner nanobeam structure. Finally, a nanobeam only consisting of inner function material is obtained when the outer high viscous material is removed.

The technical scheme of the present invention is as follows:

At the first step, the inner functional liquid and the outer high viscous liquid are delivered to the coaxial needle by two syringe pumps. Subsequently, a voltage is applied between the coaxial needle and the ground electrode, and the electrical force simultaneously acts on the inner and outer liquid. When the electrical shearing force applies on the outer high viscous liquid, the flow of the high viscous liquid can be focused and forms microscale jet, this induces a high viscous shearing force on the inner liquid. This induced high viscous shearing force is also applied on the inner liquid through the liquid-liquid interface. When the electrical shearing force, electrical field induced high viscous shearing force and internal pressure are jointly applied on the inner functional liquid, the size of the inner jet can be significantly decreased and hold stable at the nanoscale. Then, the coaxial jet with nanoscale inner jet and microscale outer jet print on a substrate with a prefabricated support structure, forming a bilayer encapsulated structure. After printing, under the effect of thermal field, the inner function liquid and outer high viscous liquid are solidified and semi-solidified respectively, and the semi-solidified outer high viscous liquid playing a role of supporting the inner nanobeam structures. Finally, a nanobeam structure only consisting of inner function material can be obtained on the substrate after removing the outer high viscous encapsulated material.

The method of manufacturing a nanobeam structure by printing, comprising the following steps:

(1) Preparation of the Substrate

The nanobeam structure mainly include the nano-freebeam and the nano-cantilever beam, so the substrates are prepared according to the form of nanobeams. The substrate used to print nano-cantilever beam is of a high temperature resistance flat-plate structure, and the substrate used to print nano-freebeam is of a high temperature resistance flat-plate structure with a prefabricated trench of a certain high aspect. The trench is prepared by means of micro/nano processing techniques of photolithograph, etching, ion beam and so on. Subsequently, an electrode is prepared on the substrate by using magnetron sputtering, vapor deposition and electroforming.

(2) Formation of Coaxial Jet

According to the requirements for the nanobeam structure material, an inner function material and an outer high viscous material are injected in the coaxial needle by two micro syringe pumps, respectively. The coaxial needle is connected to a high voltage power supply. A stable coaxial jet on the tip of coaxial needle can be obtained under the working parameters of the flow rate of inner liquid at the range of 1 pL/min-5 pL/min, the flow rate of outer liquid at the range of 100 nL/min-150 nL/min, the applied voltage at the range of 500 V to 1000 V, and the coaxial needle-substrate distance at the range of 500 μm-1 mm.

(3) Printing of Nanobeam Structure

The substrate is fixed on a motion stage by a vacuum adsorption device, which is moved at the speed of 80 mm/s-100 mm/s. The substrate is perpendicular to the coaxial needle, a linear bilayer encapsulated structure consisting of inner function material and outer high viscous material can be obtained when the coaxial jet printed on the substrate. After printing, under the effect of thermal field, the inner function liquid and outer high viscous liquid are solidified and semi-solidified respectively, and the semi-solidified outer high viscous liquid plays a role of supporting the inner nanobeam structure. Finally, a nanobeam structure only consisting of inner function material is formed on the substrate when the outer high viscous material is removed by the methods of pyrolysis or solution dissolution.

The present invention has the following advantages. In this method, under the combination action of electric field, thermal field and flow field, a stable coaxial jet is formed and used to print linear bilayer encapsulated structure on a substrate with a prefabricated support structure. In the coaxial jet, the nanoscale inner liquid consisting of functional material is encapsulated by the microscale outer liquid consisting of high viscous material, which has the capability to directly print functional nanobeam structures. This high viscous material eliminates the disturbance of external micro-environment, and plays a role of supporting the printed inner structure before complete solidification of the inner material. The nanobeam structures only consisting of inner function material is formed on the substrate when the outer high viscous encapsulated material is removed. The advantages of manufacturing nanobeam structure by coaxial focused electrohydrodynamic jet printing technique include simple process, high consistency and high efficiency. Thereby, this method provides an effective way for nanostructure fabrication with low cost and rapid manufacturing.

### BRIEF DESCRIPTION OF THE DRAWINGS

FIG. 1. Schematic diagram of the printing device.

FIG. 2. The process flow diagram of printing nanobeam.

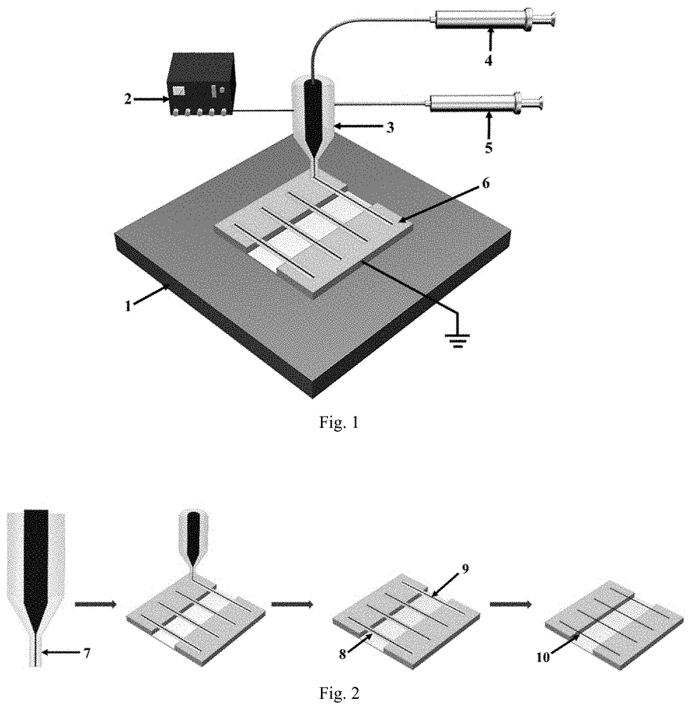

Legends: 1. X-Y motion stage; 2. High-voltage power supply; 3. Coaxial needle; 4. Micro syringe pump;

5. Micro syringe pump; 6. Substrate with prefabricated support structure; 7. Coaxial cone-jet; 8. Microscale outer encapsulated structure;

9. Nanoscale inner function structure; 10. Nanobeam.

### DETAILED DESCRIPTION

Specific implementation of the present invention is described in detail combining with the technical schemes and explained drawings. The example mainly includes substrate preparation, formation of coaxial jet, and manufacturing of nanobeam structure by printing.

The specific implementation steps of the example are as follows:

(1). Substrate Preparation

A single side polished monocrystalline silicon wafer is oxidized in a tubular furnace for 3.5 hours. Then a trench with width of 20 μm and depth of 5 μm is prepared on the surface of the oxidized silicon wafer by using photolithography and wet etching techniques. Subsequently, a pair of platinum electrodes with the thickness of 200 nm are deposited on both sides of the trench by using photolithograph, magnetron sputtering and lift off techniques.

(2). Formation of Coaxial Jet

The selected inner function material of PZT sol and outer high viscous material of silicone oil are injected in the coaxial needle (3) by micro syringes pumps (4), (5), respectively. The coaxial needle is connected to a high-voltage power supply (2). A stable coaxial cone-jet (7) consisting of inner function material of PZT sol and outer high viscous encapsulated material of silicone oil can be formed when the working parameters of the flow rate of inner material, flow rate of outer material, applied voltage, coaxial needle-substrate distance are set to 2 pL/min, 1 nL/min, 600 V, and 600 μm, respectively.

(3). Printing of Nanobeam Structure

The substrate with a prefabricated trench (6) is fixed to the motion stage (1) by using a vacuum adsorption device. The substrate is perpendicular to the coaxial needle, a linear bilayer encapsulated structure consisting of inner function material of PZT and outer high viscous material of silicone oil can be obtained when the coaxial jet print on the substrate. During printing process, the substrate moves with the motion stage at a speed of 100 mm/s. After printing, under the effect of thermal field, the nanoscale inner function material of PZT (9) and microscale outer high viscous encapsulated material of silicone oil (8) are solidified and semi-solidified respectively, and the semi-solidified outer high viscous material of silicone oil plays a role of supporting the inner PZT nanobeam structure. Finally, a PZT nanobeam structure (10) only consisting the inner function material of PZT is formed on the substrate when the outer high viscous material of silicone oil is removed by the methods of pyrolysis or solution dissolution.

The present invention proposes a method of manufacturing the nanobeam structure by printing, named coaxial focused electrohydrodynamic jet printing. In this method, under the combined action of electric field, thermal field and flow field, a stable coaxial jet is formed and used to print linear bilayer encapsulated structure on a substrate with a prefabricated support structure. Within the coaxial jet, the nanoscale inner liquid consisting of functional material is encapsulated by the microscale outer liquid consisting of high viscous material, which has the capability to directly print functional nanobeam structures. This high viscous material eliminates the disturbance of external micro-environment, and plays a role of supporting the printed inner structure before complete solidification of the inner material. A nanobeam structure only consisting of inner function material is formed on the substrate when the outer high viscous encapsulated material is removed. The advantages of manufacturing nanobeam structures by coaxial focused electrohydrodynamic jet printing technique include simple process, high consistency and high efficiency. Thereby, this method provides an effective method for nanostructure fabrication with low cost and rapid manufacturing.

1. A printing method of manufacturing nanobeam structures, comprising the following steps:
preparing a substrate, wherein the nanobeam structure mainly includes a nano-freebeam and a nano-cantilever beam, so the substrates are prepared according to the form of nanobeams; the substrate used to print the nano-cantilever beam is of a high temperature resistance flat-plate structure, and the substrate used to print the nano-freebeam is of a high temperature resistance flat-plate structure with a prefabricated trench of a certain high aspect; the trench is prepared by means of micro/nano processing techniques of photolithograph, etching, ion beam and so on; subsequently, an electrode is prepared on the substrate by using magnetron sputtering, vapor deposition and electroforming;
forming a coaxial jet, wherein, according to the requirements for the nanobeam structure material, an inner function material and an outer high viscous material are injected in a coaxial needle by two micro syringe pumps, respectively; the coaxial needle is connected to a high voltage power supply; a stable coaxial jet on the tip of the coaxial needle can be obtained under the working parameters of the flow rate of an inner liquid at a range of 1 pL/min-5 pL/min, the flow rate of an outer liquid at the range of 100 nL/min-150 nL/min, an applied voltage at the range of 500 V to 1000 V, and a coaxial needle-substrate distance at the range of 500 pan-1 mm; and
printing of nanobeam structure, wherein the substrate is fixed on a motion stage by a vacuum adsorption device, which is moved at the speed of 80 mm/s-100 mm/s; the substrate is perpendicular to the coaxial needle, a linear bilayer encapsulated structure consisting of an inner function material and an outer high viscous material can be obtained when the coaxial jet is printed on the substrate; after printing, under the effect of a thermal field, the inner function liquid and outer high viscous liquid are solidified and semi-solidified respectively, and the semi-solidified outer high viscous liquid plays a role of supporting an inner nanobeam structure; finally, a nanobeam structure only consisting of inner function material is formed on the substrate when the outer high viscous material is removed by the methods of pyrolysis or solution dissolution.
